(19) United States
(12) Patent Application Publication
(10) Pub. No.: US 2022/0115348 A1
(43) Pub. Date: Apr. 14, 2022

(54) 3D MODIFIED SURFACE TO ENABLE IMPROVED BOND STRENGTH AND YIELD OF ELECTRICAL INTERCONNECTIONS

(71) Applicant: Raytheon Company, Waltham, MA (US)

(72) Inventors: Sean F. Harris, Santa Barbara, CA (US); Sean P. Kilcoyne, Lompoc, CA (US); Aaron M. Ramirez, Santa Barbara, CA (US); Joseph N. Wilde, Ventura, CA (US)

(21) Appl. No.: 17/067,955

(22) Filed: Oct. 12, 2020

(51) Int. Cl. H01L 23/00

(52) U.S. Cl. CPC H01L 24/16; H01L 24/13; H01L 24/81; H01L 2224/13109; H01L 2224/81801; H01L 2224/1357; H01L 2224/13687; H01L 2224/1607; H01L 2224/81345; H01L 2224/13565

(57) ABSTRACT

An electronic device for interconnection with an integrated circuit device is provided. The electronic device includes an interconnection surface configured to oppose the integrated circuit device with an interconnect structure disposed therebetween. The electronic device also includes at least one electronic device contact pad disposed on the interconnection surface for bonding to the interconnect structure. The at least one electronic device contact pad has at least one 3-dimensional projection configured to extend from the electronic device contact pad toward the integrated circuit device. The at least one 3-dimensional projection is configured to aid in bonding the electronic device contact pad to the interconnect structure to electrically couple the electronic device to the integrated circuit device.

### TECHNICAL FIELD

The present invention relates generally to electrical interconnections in integrated circuits and more particularly to hybridization techniques for improved bonding in electrical interconnections.

### BACKGROUND

Indium bump interconnects are commonly used in semiconductor device hybridization techniques to interconnect electronic devices (for example, semiconductor chips and detectors) to integrated circuit devices (for example, read out integrated circuits (ROICs)). Specifically, prior to hybridization, indium bumps are deposited over contact pads of the electronic device and/or the integrated circuit device. The contact pads are then aligned and pressed together to form an electrically conductive bond between the electronic device and the integrated circuit device. A problem often faced with this hybridization technique is the formation of, for example, indium oxide on the indium bumps when they are exposed to air or during various processes prior to hybridization. Indium oxide typically forms as a film on the indium bumps and may be non-uniform from bump to bump across the device. This indium oxide film acts as a barrier to contact between the contact pad of the electronic device and the indium bump and therefore prevents the formation of strong, reliable and consistent bonds there between. The reliability and performance of the electrical interconnection is therefore limited, resulting in yield degradation of the integrated circuit.

With reference to FIG. 1, a conventional electrical interconnection 10 of a ROIC 21 after hybridization using an indium bump interconnect structure 16 to electrically couple an electronic device 14 with the ROIC 21 is depicted. As depicted, an indium oxide film 20 exists on the outermost surface of the indium bump interconnect structure 16. Due to the barrier of the indium oxide film 20, a gap 18 is formed between a contact pad 12 of an electronic device 14 and the indium bump interconnect structure 16 after attempted bonding. Although the indium bump interconnect structure 16 is adequately compressed between the contact pad 12 of the electronic device 14 and the contact pad 22 of the ROIC 21, the contact pad 12 of the electronic device 14 is prevented from fully contacting and forming a consistent bond with the indium bump interconnect structure 16 because of the indium oxide film 20 barrier. In applications where both bond surfaces of the electrical interconnection 10 (the contact pad 12 of the electronic device 14 and the contact pad 22 of the ROIC 21) are planar, excessive force and/or mechanical agitation beyond that which is typically necessary to attempt to break through the indium oxide film 20 is required. In such applications, without any means to penetrate the indium oxide film 20 prior to hybridization, bonds between the contact pad 12 of the electronic device 14 and the indium bump interconnect structure 16 will be inconsistent (poor yield) and an electrical connection between the electronic device 14 and the ROIC 21 will be unreliable and/or form an open circuit.

Prior attempts to solve this problem have aimed at minimizing the indium oxide formed on indium bump interconnect structures or removing the formed indium oxide film prior to hybridization, typically via chemical surface treatments and/or additional chemical processing steps. The industry standard, for example, uses chemical etches (fluxes) and dry etch surface treatments to remove indium oxide film prior to hybridization. Although this practice may initially remove the indium oxide film on the bumps, the indium oxide immediately re-develops when again exposed to air or more processing, therefore presenting the same problems described above.

### SUMMARY

In a general embodiment, an electrical interconnection between an electronic device and an integrated circuit device is provided. The electrical interconnection includes an electronic device having contact pads configured with at least one 3-dimensional projection extending therefrom. When an interconnect structure is deposited there between, and the electronic device and the integrated circuit device are pressed together with sufficient force, the at least one 3-dimensional projection of the contact pad is configured to penetrate, or break through, an outermost layer of the interconnect structure and form a consistent bond with the interconnect structure underneath the outermost layer.

According to an aspect of the invention, an electronic device for interconnection with an integrated circuit device is provided. The electronic device includes an interconnection surface configured to oppose an integrated circuit device contact pad of the integrated circuit device with an interconnect structure disposed therebetween. The electronic device additionally includes at least one electronic device contact pad disposed on the interconnection surface for bonding to the interconnect structure. The at least one electronic device contact pad has at least one 3-dimensional projection configured to extend from the electronic device contact pad toward the integrated circuit device contact pad. The at least one 3-dimensional projection is configured to aid in bonding the electronic device contact pad of the electronic device to the interconnect structure to electrically couple the electronic device to the integrated circuit device.

According to an embodiment of any paragraph(s) of this summary, the at least one 3-dimensional projection includes a plurality of discrete 3-dimensional projections.

According to another embodiment of any paragraph(s) of this summary, the plurality of discrete 3-dimensional projections are evenly distributed on the electronic device contact pad.

According to another embodiment of any paragraph(s) of this summary, the plurality of discrete 3-dimensional projections are randomly distributed on the electronic device contact pad.

According to another embodiment of any paragraph(s) of this summary, the at least one 3-dimensional projection is circular.

According to another embodiment of any paragraph(s) of this summary, the at least one 3-dimensional projection is linear.

According to another aspect of the invention, an electrical interconnection for an integrated circuit is provided. The electrical interconnection includes an integrated circuit device including at least one integrated circuit device contact pad, and an electronic device electrically interconnected with the integrated circuit device. The electronic device includes an interconnection surface opposing the integrated circuit device contact pad and at least one electronic device contact pad disposed on the interconnection surface. The at least one electronic device contact pad has at least one 3-dimensional projection extending from the electronic device contact pad toward the at least one integrated circuit device contact pad. The electrical interconnection also includes an interconnect structure disposed between and bonded to the at least one integrated circuit device contact pad and the at least one electronic device contact pad to electronically couple the electronic device to the integrated circuit device. The at least one 3-dimensional projection of the at least one electronic device contact pad aids in bonding the at least one electronic device contact pad to the interconnect structure.

According to an embodiment of any paragraph(s) of this summary, the integrated circuit device is part of a read out integrated circuit (ROIC).

According to another embodiment of any paragraph(s) of this summary, the interconnect structure is an indium bump interconnect structure.

According to another embodiment of any paragraph(s) of this summary, the indium bump interconnect structure includes a film of indium oxide on an outermost surface thereof and the at least one 3-dimensional projection is configured to penetrate the film of the indium oxide and bond to the indium bump interconnect structure.

According to another aspect of the invention, a method of manufacturing an electronic device for interconnection with an integrated circuit device in an integrated circuit is provided. The method includes a step of providing the electronic device. The electronic device includes an interconnection surface configured to oppose the integrated circuit device with an interconnect structure disposed therebetween. At least one electronic device contact pad is disposed on the interconnection surface for bonding to the interconnect structure. The method also includes a step of forming at least one 3-dimensional projection on the at least one electronic device contact pad. The at least one 3-dimensional projection is configured to extend from the electronic device contact pad toward the integrated circuit device and is configured to aid in bonding the electronic device contact pad to the interconnect structure to electrically couple the electronic device to the integrated circuit device.

According to an embodiment of any paragraph(s) of this summary, the forming includes depositing material onto at least a part of the at least one electronic device contact pad to form the at least one 3-dimensional projection on a surface of the electronic device contact pad configured to oppose the integrated circuit device.

According to another embodiment of any paragraph(s) of this summary, the forming includes removing material from at least part of the at least one electronic device contact pad to form the at least one 3-dimensional projection on a surface of the electronic device contact pad configured to oppose the integrated circuit device.

According to another embodiment of any paragraph(s) of this summary, the removing includes a wet etch technique.

According to another embodiment of any paragraph(s) of this summary, the removing includes a dry etch technique.

According to another aspect of the invention, a method of forming an electrical interconnection between an electronic device and an integrated circuit device is provided. The method includes a step of providing the electronic device. The electronic device includes an interconnection surface configured to oppose the integrated circuit device with an interconnect structure disposed therebetween. At least one electronic device contact pad is disposed on the interconnection surface for bonding to the interconnect structure. The at least one electronic device contact pad includes at least one 3-dimensional projection configured to extend from the electronic device contact pad toward the integrated circuit device. The method additionally includes a step of providing the integrated circuit device having at least one integrated circuit device contact pad. The method then includes a step of depositing the interconnect structure on at least one of the electronic device contact pad and/or the integrated circuit device contact pad. The method then additionally includes a step of aligning the electronic device contact pad with the integrated circuit device contact pad and a step of pressing the electronic device contact pad and the integrated circuit contact pad together with the interconnect structure therebetween to form an electrical connection between the electronic device and the integrated circuit device.

The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF DRAWINGS

The annexed drawings show various aspects of the invention.

FIG. 1 is a schematic diagram of a prior art electrical interconnection.

FIG. 2 is a schematic diagram of an electrical interconnection according to an embodiment of the present invention.

FIG. 3 is a schematic diagram of an electronic device of the electrical interconnection of FIG. 2.

FIG. 4A-I are schematic diagrams of various embodiments of 3-dimensional projections on an electronic device contact pad of the electronic device of FIG. 3.

FIG. 5 is a flowchart of a method of manufacturing an electronic device for interconnection with an integrated circuit device.

FIG. 6 is a flowchart of a method of forming an electrical interconnection between an electronic device and an integrated circuit device.

### DETAILED DESCRIPTION

According to a general embodiment, an electrical interconnection between an electronic device (for example, an integrated circuit chip or detector) to an integrated circuit device (for example, a read out integrated circuit (ROIC), a printed circuit board (PCB), a patterned ceramic substrate, or another integrated circuit chip) is provided. The electrical interconnection includes an electronic device having contact pads configured with at least one 3-dimensional projection extending therefrom (toward contact pads of the integrated circuit device). When an interconnect structure is deposited therebetween for hybridization, and the electronic device and the integrated circuit device are pressed together with sufficient force, the at least one 3-dimensional projection of the electronic device contact pad is configured to penetrate, or break through, an outermost layer of the interconnect structure and form a consistent bond with the interconnect structure underneath the outermost layer. For example, in an embodiment in which the interconnect structure is an indium bump interconnect structure, the at least one 3-dimensional projection of the electronic device contact pad is configured to penetrate, or break through, any indium oxide film that may be formed on the outermost layer of the indium bump interconnect structure. In this way, upon pressing the electronic device and the integrated circuit device together with sufficient force, the at least one 3-dimensional projection of the electronic device contact pad is configured to contact and form a consistent bond with the exposed indium bump interconnect structure underneath the penetrated indium oxide film thereon, which otherwise may have prevented contact and bonding between the contact pad of the electronic device and the indium bump interconnect structure.

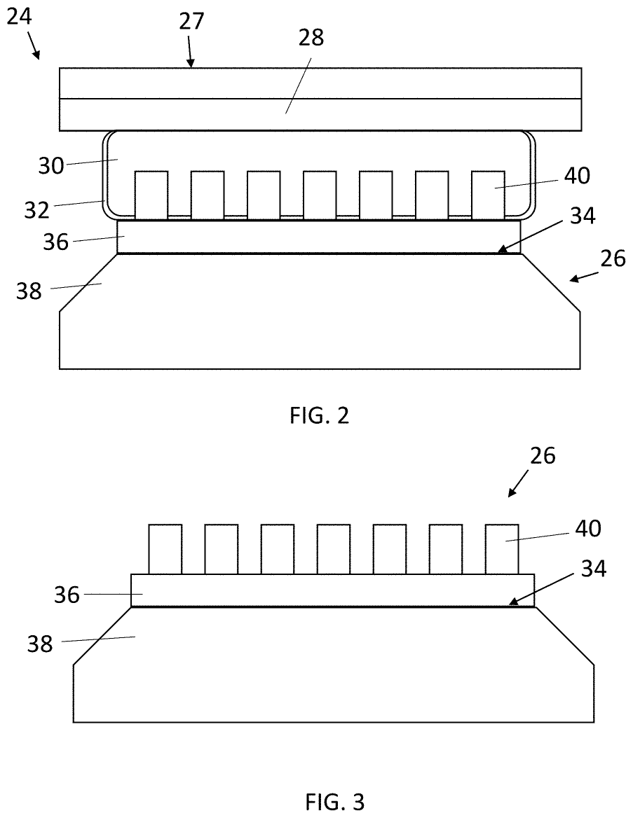

Referring to FIG. 2, an exemplary electrical interconnection 24 of this type is depicted. It should be understood that the relative size of the features depicted in the figures is not necessarily to scale. For example, some features are exaggerated for purposes of illustration. The electrical interconnection 24 includes an electronic device 26 configured to be electrically interconnected with an integrated circuit device 27, having an integrated circuit device contact pad 28, via an interconnect structure 30 deposited therebetween. The electronic device 26, depicted in isolation from the integrated circuit device 27 in FIG. 3, includes an interconnection surface 34 having at least one electronic device contact pad 36 disposed thereon. The interconnection surface 34 is a surface of the electronic device 26 configured to oppose the integrated circuit device 27 when the electronic device 26 is interconnected with the integrated circuit device 27 in the electrical interconnection 24 (FIG. 2). In the depicted embodiment, the electronic device 26 includes at least one mesa 38, wherein the interconnection surface 34 includes a surface of the mesa 38 that is configured to oppose the integrated circuit device 27 when the electronic device 26 is interconnected with the integrated circuit device 27 in the electrical interconnection 24. The at least one contact pad 36 may be disposed on the interconnection surface 34 of a respective one of the at least one mesa 38. The electronic device 26 may not include any mesas 38 and may instead have a planar configuration.

The electronic device 26 is configured to be electrically interconnected with the integrated circuit device 27 via the interconnect structure 30. Specifically, the interconnect structure 30 may be deposited on at least one of the integrated circuit device contact pad 28 and the at least one electronic device contact pad 36 of the electronic device 26 prior to hybridization and the electronic device contact pad 36 and the integrated circuit device contact pad 28 being aligned and pressed together to form a bond therebetween. As already described, the interconnect structure 30 may be an indium bump interconnect structure 30, however the same principles apply to embodiments in which the interconnect structure 30 is another material. For example, the interconnect structure 30 may be made of indium silver alloys or lead silver alloys, among other suitable materials. For purposes of the present disclosure, an embodiment in which the interconnect structure 30 is an indium bump interconnect structure 30 will be described.

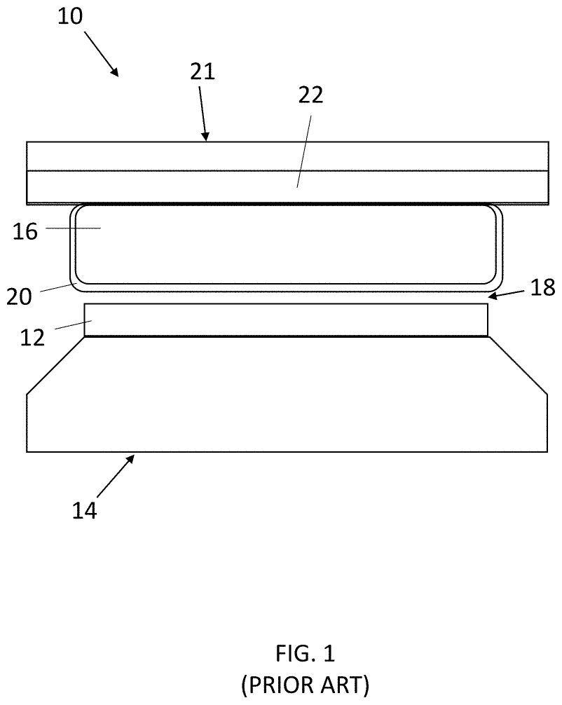

In the embodiment in which the interconnect structure 30 is an indium bump interconnect structure 30, an indium oxide film 32 may be present on an outermost surface of the indium bump interconnect structure 30. The indium oxide film 32 may be formed when the indium bump interconnect structure 30 is exposed to air or when the indium bump interconnect structure 30 undergoes various cleaning processes prior to hybridization. As previously described with reference to FIG. 1, in conventional electrical interconnections 10, the presence of the indium oxide film 20 on an outermost surface of an indium bump interconnect structure 16 presents a barrier between the electronic device contact pad 12 and the indium bump interconnect structure 16, preventing contact and bonding therebetween, and therefore is required to be removed or minimized prior to hybridization. In the embodiment of the present disclosure, however, the electronic device contact pad 36 is configured to penetrate the indium oxide film 32 and reveal the pure indium bump interconnect structure 30 underneath the indium oxide film 32. In this way, a strong, reliable, and consistent bond between the electronic device contact pad 36 and the indium bump interconnect structure 30 is able to form despite the presence of the indium oxide film 32 on the outermost surface of the indium burn interconnect structure 30.

Specifically, the at least one electronic device contact pad 36 includes at least one 3-dimensional projection 40 configured to extend from the at least one electronic device contact pad 36 toward the integrated circuit device contact pad 28 and interconnect structure 30 prior to hybridization. A material of the 3-dimensional projection 40 may include a conductive material and, for example, may be the same material as the electronic device contact pad 36. The at least one 3-dimensional projection 40 may be of any suitable size, depending on the size of the contact pad 36 and the indium bump interconnect structure 30. For example, the at least one 3-dimensional projection 40 may be between 5 to 50 microns long. Additionally, the at least one 3-dimensional projection 40 may include a plurality of 3-dimensional projections 40. The number of 3-dimensional projections 40 may also depend on the size of the contact pad 36, the indium bump interconnect structure 30 and each individual 3-dimensional projection 40 and may be optimized based on modelling and/or empirical evidence.

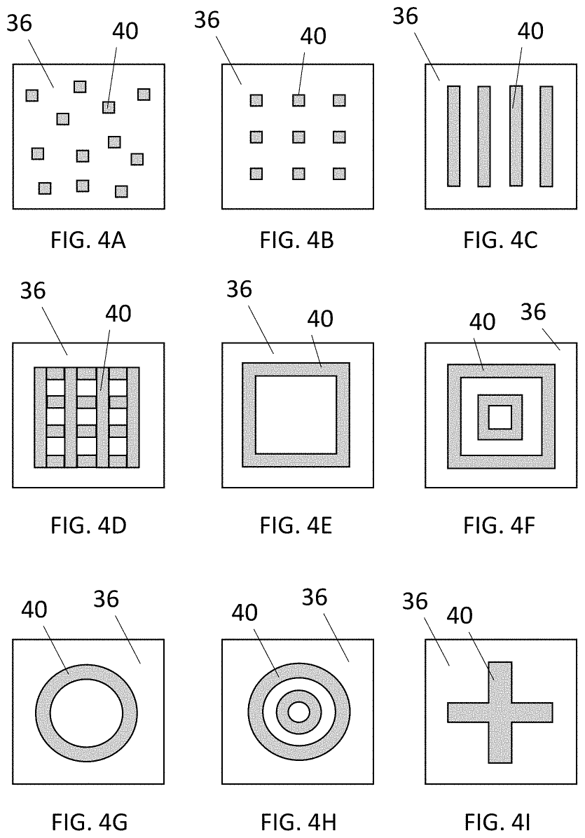

With reference to FIGS. 4A-I, the at least one 3-dimensional projection 40 may be of any shape and may be arranged in any number of ways on the contact pad 36. For example, the at least one 3-dimensional projection 40 may include a plurality of discrete 3-dimensional projections (e.g., FIGS. 4A, 4B, 4C, 4F, 4H). These discrete 3-dimensional projections 40 may be, for example, generally cylindrical, rectangular, spiked, or curved. The plurality of discrete 3-dimensional projections may be patterned or evenly distributed on the contact pad 36 (e.g., FIGS. 4B, 4C, 4F, 4H) or may be arbitrarily or randomly distributed on the contact pad 36 (e.g., FIG. 4A). The arrangement of the at least one 3-dimensional projection 40 may be, for example, linear (e.g., FIG. 4C), circular (e.g., FIGS. 4G, 4H), polygonal (e.g., FIGS. 4E, 4F), in a grid shape (e.g., FIG. 4D), in a cross shape (e.g., FIG. 4I), or any other suitable shape or arrangement. In an embodiment in which the at least one 3-dimensional projection 40 includes a plurality of discrete 3-dimensional projections 40, the plurality of discrete 3-dimensional projections 40 may be arranged symmetrically, concentrically, or otherwise in an orderly fashion relative to each other. It will be understood that the above-described and depicted embodiments of the at least one 3-dimensional projection 40 are non-limiting examples and that any number of other suitable shapes and arrangements may be applicable to the present disclosure. Additionally, any combination of shapes and arrangements may also be applicable to the present disclosure.

In any embodiment or combination, the at least one 3-dimensional projection 40 creates a non-planar topography of the contact pad 36 and increases the surface area of the contact pad 36 for improved bonding between the contact pad 36 and the interconnect structure 30. Accordingly, the at least one 3-dimensional projection 40 is configured to impart increased contact force and/or mechanical agitation on the interconnect structure 30 when pressed together, compared to a planar surface, to penetrate, or break through, an outermost surface of the interconnect structure 30 and form a reliable, high strength bond between the contact pad 36 and the interconnect structure 30 underneath the outermost surface of the interconnect structure 30.

Specifically in the embodiment in which the interconnect structure 30 is the indium bump interconnect structure 30, for example, the indium oxide film 32 on the outermost surface of the indium bump interconnect structure 30 does not need to be minimized or removed prior to hybridization to form strong, reliable, and consistent bonds between the contact pad 36 and the interconnect structure 30. Instead, the at least one 3-dimensional projection 40 of the contact pad 36 mechanically penetrates the indium oxide film 32 on the outermost surface of the indium bump interconnect structure 30.

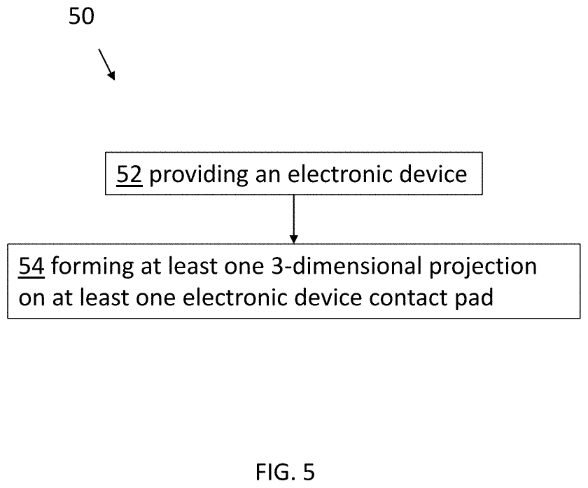

With reference to FIG. 5, a method 50 of manufacturing an electronic device for interconnection with an integrated circuit device is provided. The method includes a step 52 of providing the electronic device. The electronic device includes an interconnection surface configured to oppose the integrated circuit device with an interconnection structure disposed therebetween. At least one electronic device contact pad is disposed on the interconnection surface for bonding to the interconnect structure. The method 50 then includes a step 54 of forming at least one 3-dimensional projection on the at least one electronic device contact pad. The at least one 3-dimensional projection is configured to extend from the electronic device contact pad toward the integrated circuit device and to aid in bonding the electronic device contact pad to the interconnect structure to electrically couple the electronic device to the integrated circuit device.

The step 54 of forming the at least one 3-dimensional projection may include depositing material onto at least part of the at least one electronic device contact pad to form the at least one 3-dimensional projection on a surface of the electronic device contact pad configured to oppose the integrated circuit device. The material may include a conductive material and, for example, may be the same material as the electronic device contact pad. In this way, the electronic device contact pad may be built up in certain areas on the electronic device contact pad to form a non-planar topography of the electronic device contact pad and increase the surface area thereof. For example, photolithography lift-off defined deposition may be used to deposit specific 3-dimensional shapes to form the at least one 3-dimensional projection. In another embodiment, the step of forming the at least one 3-dimensional projection may include removing material from at least part of the at least one electronic device contact pad to form the at least one 3-dimensional projection on a surface of the electronic device contact pad configured to oppose the integrated circuit device. In this way, the electronic device contact pad may be, for example, etched away in certain areas on the electronic device contact pad to form a non-planar topography of the electronic device contact pad and increase the surface area thereof. For example, the removing may include a wet etching technique or a dry etching technique.

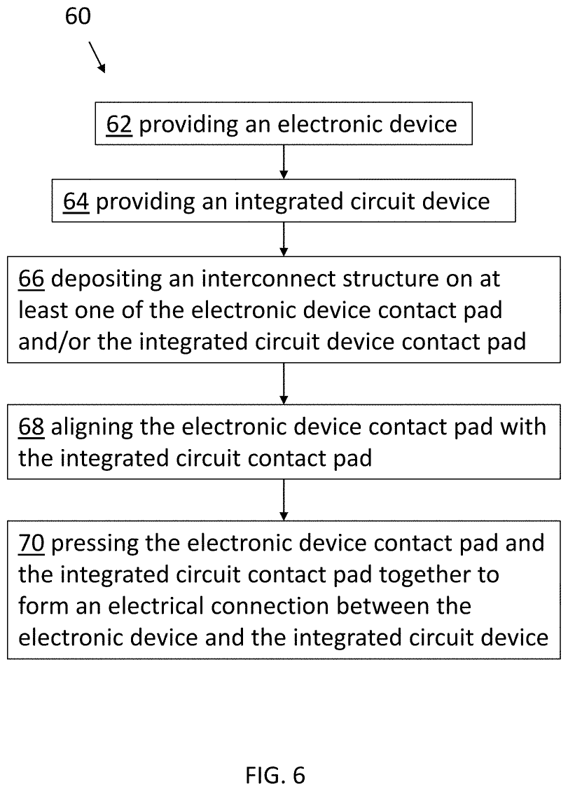

With reference to FIG. 6, a method 60 of forming an electrical interconnection between an electronic device and an integrated circuit device is also provided. The method 60 includes a step 62 of providing the electronic device. The electronic device includes an interconnection surface configured to oppose the integrated circuit device with an interconnection structure disposed therebetween. At least one electronic device contact pad is disposed on the interconnection surface for bonding to the interconnect structure. The at least one electronic device contact pad includes at least one 3-dimensional projection configured to extend from the electronic device contact pad toward the integrated circuit device. The at least one 3-dimensional projection is configured to aid in bonding the electronic device contact pad to the interconnect structure to electrically couple the electronic device to the integrated circuit device.

The method 60 additionally includes a step 64 of providing the integrated circuit device having at least one integrated circuit device contact pad. The integrated circuit device may be, for example, part of an ROIC. The method 60 then includes a step 66 of depositing the interconnect structure on at least one of the electronic device contact pad and/or the integrated circuit device contact pad. For example, the interconnect structure may be deposited on the at least one electronic device contact pad. The method 60 then includes a step 68 of aligning the electronic device, particularly the at least one electronic device contact pad, with the integrated circuit device, particularly the integrated circuit device contact pad, and a step 70 of pressing the electronic device and the integrated circuit device together with the interconnect structure therebetween. A force required for the step 70 of pressing will depend on the size of the electronic device and the integrated circuit device, as well as the size and arrangement of the at least one 3-dimensional projection.

Upon the step 70 of pressing the electronic device and the integrated circuit device together with the interconnect structure therebetween, the at least one 3-dimensional projection of the contact pad is configured to penetrate, or break through, an outermost surface of the interconnect structure. A reliable, high strength, and consistent bond may then be formed between the electronic device contact pad and the interconnect structure underneath the outermost surface of the interconnect structure to form an electrical connection between the electronic device and the integrated circuit device.

Although the invention has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application. For example, aspects and features of the invention may be applied to flip-chip bonding of an electronic device onto another electronic device, PCB, or patterned ceramic substrate.

1. An electronic device for interconnection with an integrated circuit device, the electronic device comprising:
an interconnection surface configured to oppose an integrated circuit device contact pad of the integrated circuit device with an interconnect structure disposed therebetween; and
at least one electronic device contact pad disposed on the interconnection surface for bonding to the interconnect structure, the at least one electronic device contact pad having at least one 3-dimensional projection configured to extend from the electronic device contact pad toward the integrated circuit device contact pad, the at least one 3-dimensional projection being configured to aid in bonding the electronic device contact pad to the interconnect structure to electrically couple the electronic device to the integrated circuit device.

2. The electronic device according to claim 1, wherein the at least one 3-dimensional projection includes a plurality discrete 3-dimensional projections.

3. The electronic device according to claim 2, wherein the plurality of discrete 3-dimensional projections are evenly distributed on the electronic device contact pad.

4. The electronic device according to claim 2, wherein the plurality of discrete 3-dimensional projections are randomly distributed on the electronic device contact pad.

5. The electronic device according to claim 4, wherein the at least one 3-dimensional projection is circular.

6. The electronic device according to any one of claim 1, wherein the at least one 3-dimensional projection is linear.

7. An electrical interconnection for an integrated circuit comprising:
an integrated circuit device including at least one integrated circuit device contact pad,
an electronic device electrically interconnected with the integrated circuit device, the electronic device including an interconnection surface opposing the integrated circuit device contact pad and at least one electronic device contact pad disposed on the interconnection surface, the at least one electronic device contact pad having at least one 3-dimensional projection extending from the electronic device contact pad toward the integrated circuit device contact pad, and
an interconnect structure disposed between and bonded to the at least one integrated circuit device contact pad and the at least one electronic device contact pad to electronically couple the electronic device to the integrated circuit device,
wherein the at least one 3-dimensional projection of the at least one electronic device contact pad aids in bonding the at least one electronic device contact pad to the interconnect structure.

8. The electronic interconnection according to claim 7, wherein the integrated circuit device is part of a read out integrated circuit (ROIC).

9. The electronic interconnection according to claim 7, wherein the interconnect structure is an indium bump interconnect structure.

10. The electronic interconnection according to claim 9, wherein the indium bump interconnect structure includes a film of indium oxide on an outermost surface thereof, wherein the at least one 3-dimensional projection is configured to penetrate the film of indium oxide and bond to the indium bump interconnect structure.

11. The electronic device according to claim 7, wherein the at least one 3-dimensional projection includes a plurality discrete projections.

12. The electronic device according to claim 11, wherein the plurality of discrete projections are evenly distributed on the electronic device contact pad.

13. The electronic device according to claim 11, wherein the plurality of discrete projections are randomly distributed on the electronic device contact pad.

14. The electronic device according to claim 7, wherein the at least one 3-dimensional projection is circular.

15. The electronic device according to claim 7, wherein the at least one 3-dimensional projection is linear.

16. A method of manufacturing an electronic device for interconnection with an integrated circuit device in an integrated circuit, the method comprising:
providing the electronic device, the electronic device including an interconnection surface configured to oppose the integrated circuit device with an interconnect structure disposed therebetween, and at least one electronic device contact pad disposed on the interconnection surface for bonding to the interconnect structure,
forming at least one 3-dimensional projection on the at least one electronic device contact pad, the at least one 3-dimensional projection configured to extend from the electronic device contact pad toward the integrated circuit device and to aid in bonding the electronic device contact pad to the interconnect structure to electrically couple the electronic device to the integrated circuit device.

17. The method according to claim 16, wherein the forming includes depositing material onto at least part of the at least one electronic device contact pad to form the at least one 3-dimensional projection on a surface of the electronic device contact pad configured to oppose the integrated circuit device.

18. The method according to claim 16, wherein the forming includes removing material from at least part of the at least one electronic device contact pad to form the at least one 3-dimensional projection on a surface of the electronic device contact pad configured to oppose the integrated circuit device.

19. The method according to claim 18, wherein the removing includes a wet etch technique.

20. The method according to claim 18, wherein the removing includes a dry etch technique.
